(19) United States
(12) Patent Application Publication
(10) Pub. No.: US 2017/0295997 A1
(43) Pub. Date: Oct. 19, 2017

(54) CAPACITIVE TOUCH FACEPLATE FOR A BLENDER

(71) Applicant: Vita-Mix Management Corporation, Olmsted Township, OH (US)

(72) Inventors: David J. Kolar, Stow, OH (US); Jack Warren Gee, II, Willoughby, OH (US)

(21) Appl. No.: 15/515,888

(22) PCT Filed: Oct. 13, 2015
(86) PCT No.: PCT/US2015/055303

§ 371 Date: Mar. 30, 2017

Related U.S. Application Data
(60) Provisional application No. 62/063,010, filed on Oct. 13, 2014.

(51) Int. Cl. A47J 43/046; H03K 17/96; A47J 43/07

(52) U.S. Cl. CPC A47J 43/046; A47J 43/07; H03K 17/9622

(57) ABSTRACT

Touch sensors form various controls for a touch controller of a blender. The controls are arranged on the touch controller such that a user holding the blender can operate the blender by articulating their thumbs. In one example, button controls for preset programs are arranged in an arcuate manner on one side of the touch controller, the curvature of the arcuate shape being open to the side of the blender. A button for a pulsating function may be located inside the curvature opening. Start and stop buttons may be located near the bottom in the middle of the touch controller. A vertical sliding speed control may be located on the side of the touch controller opposite the button controls. The touch controller may also have an LED or LCD screen.

### CROSS-REFERENCE TO RELATED APPLICATION

This application claims the benefit of U.S. Provisional Application No. 62/063,010, filed Oct. 13, 2014, which is incorporated in its entirety herein by reference.

### FIELD

The disclosure described herein relates to a home appliance with touch controls. More particularly, the disclosure described herein relates to a capacitive touch control for a blender.

### BACKGROUND

While operating many home appliances, particularly those in the kitchen, it is often necessary or beneficial for a user to maintain visual focus on the operation of the appliance while blindly controlling the function of the appliance. For example, when operating a blender, a user must watch the blending container to monitor the blending process and condition of the ingredients. At the same time, it is often necessary to hold the lid with one hand while pressing a button or buttons to maintain operation of the blender at an appropriate speed. In other words, a user may need to operate the appliance without looking at the controls.

For appliances with mechanical controls, the act of controlling the appliance can provide users with a tactile response through the use of switches, knobs, and/or buttons. Rotation of the wrist, for example, can signal the degree a rotary speed or power dial is turned, thus indicating the selected speed or power; raised or depressed buttons and switches indicate the location of certain controls; and the orientation of flipped or depressed switches indicate the current state of that control. However, for touch controls that are based on capacitive touch, resistive touch, infrared sensors, and the like, such tactile feedback does not exist. That is, users operating an appliance with touch controls may lose orientation of the controls and the controls do not provide any physical place for fingers to rest.

### BRIEF SUMMARY

A simplified summary is provided herein to facilitate a basic or general understanding of various aspects of exemplary, non-limiting embodiments that follow in the more detailed description and the accompanying drawings. This summary is not intended, however, as an extensive or exhaustive overview. Instead, the sole purpose of the summary is to present some concepts related to some exemplary non-limiting embodiments in a simplified form as a prelude to the more detailed description of the various embodiments that follow.

According to one example of the device described herein, a blending apparatus comprises an input apparatus; a controller; a motor; and a container, wherein the input apparatus comprises a plurality of touch sensors arranged to form a plurality of touch controls, the plurality of touch controls arranged to be operated by articulation of a user's thumb about an axis of rotation while holding the blending apparatus. In various embodiments of the above example, the input apparatus comprises first side, second side, and middle portions, wherein the plurality of touch controls comprise buttons corresponding to a plurality of blending programs on the first side portion, a speed control on the second side portion, and start and stop buttons in the middle portion, and wherein, the plurality of blending programs are arranged, in part, in an arcuate manner; a touch control for a pulsating function is arranged in the curvature defined by the arcuate arrangement of the buttons corresponding to the plurality of blending programs; the curvature defined by the arcuate arrangement opens to the first side of the blending apparatus; the speed control is a slider control; the plurality of blending programs comprise programs for operating the blending apparatus to create smoothies, frozen desserts, and hot soups; the plurality of blending programs comprise programs for operating the blending apparatus to create purees and to clean the blending apparatus; the plurality of touch sensors comprise at least one capacitive touch sensor; the input apparatus comprises an LED or LCD screen on which the touch controls are displayed; the controller is capable of dynamically altering an arrangement or appearance of the touch controls on the screen; and/or the input apparatus comprises at least one of a series of sounds or vibrations for each of the plurality of touch controls.

According to another example of the device described herein, an input apparatus for a kitchen appliance comprises first side, second side, and middle portions; and a plurality of touch sensors arranged to form a plurality of touch controls, wherein the plurality of touch controls comprise buttons corresponding to a plurality of programs relating to the operation of the kitchen appliance on a first side portion and start and stop buttons in one of the middle portion and the second side portion, wherein the plurality of touch controls are arranged to be operated by articulation of a user's thumb about an axis of rotation while holding the kitchen appliance. In various embodiments of the above example, the buttons are arranged in an arcuate shape, the curve of the arcuate shape opening toward the first side of the kitchen appliance; the kitchen appliance is a blender; the plurality of touch sensors comprise at least one capacitive touch sensor; the input apparatus further comprises an LED or LCD screen; an arrangement or appearance of the touch controls can be dynamically altered on the screen; the screen is divided into multiple sections corresponding to the plurality of touch controls and illuminates in one or more different colors according to an activated touch control and relative speed; the input apparatus further comprises at least one of a series of sounds or vibrations for each of the plurality of touch controls; and/or the plurality of touch controls are arranged to be operated by articulation of the user's thumb on one hand while activating a speed control with the user's thumb on the other hand.

These and other embodiments are described in more detail below.

### BRIEF DESCRIPTION OF THE DRAWINGS

FIG. 1 is a block diagram that demonstrates various operations that take place during the use of a blender;

FIG. 2 illustrates a perspective view of an embodiment of a blender having a touch control input apparatus;

FIG. 3 illustrates an embodiment of an input apparatus with touch control for a blender operated by a user's thumb;

FIG. 4 illustrates an embodiment of an input apparatus with touch control for a blender operated by a user's thumb in a different location; and

FIG. 5 illustrates another embodiment of an input apparatus with touch control for a blender operated by a user's thumb.

### DETAILED DESCRIPTION OF THE DRAWINGS

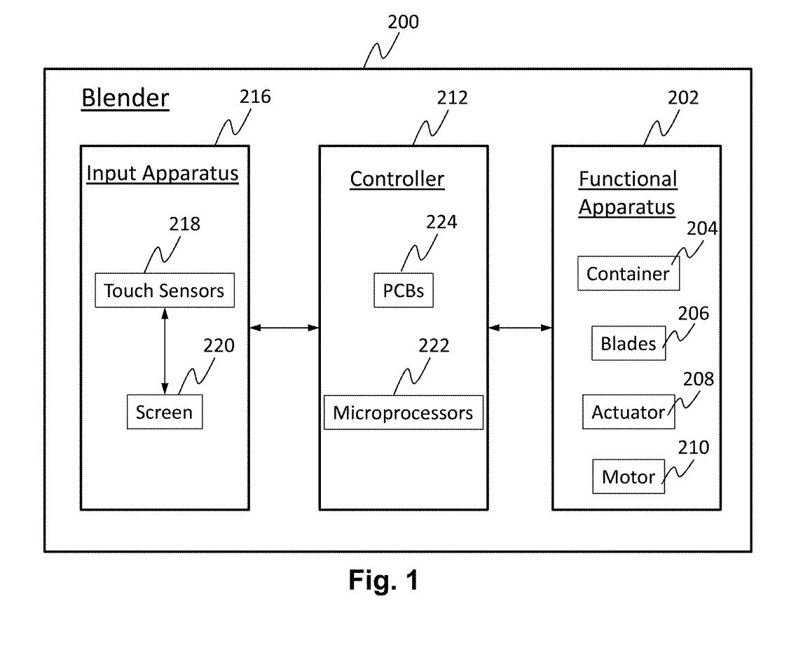

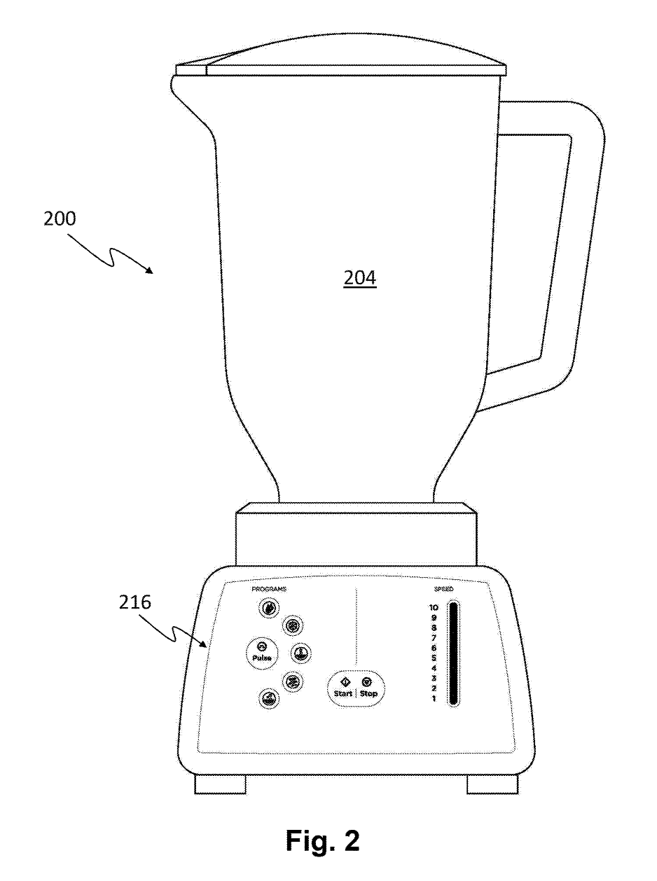

The device described herein relates to a touch control for kitchen appliances including home/consumer and commercial appliances, and more specifically, to a touch control for a blender. For the purposes of this disclosure, the touch control will be described herein as relating to a blender only for exemplary purposes. However, it is to be understood that the utility of the present disclosure is applicable to any kitchen appliance. Referring to FIG. 1, the blender 200, can generally be described as comprising a functional apparatus 202 (e.g., a container 204, blades 206, actuators 208, motor 210, and the like), a controller 212, and an input apparatus 216. A user interfaces with the functional apparatus 202 of the blender 200 through an input apparatus 216 on a base of the blender by operating buttons, switches, and various controls that generate an electric signal. Such a blender 200 with container 204 and input apparatus 216 is illustrated in FIG. 2. The controller 212 translates electrical signals, generated by the input apparatus 216 in response to actuation by a user, to operate the actuators 208, motors 210, blades 206 and the like of the functional apparatus 202 of the blender 200. A “controller” as used herein refers to any, or part of any, electrical circuit comprised of any number of electrical components, including, for example, resistors, transistors, capacitors, inductors, and the like. The circuit may be of any form, including, for example, an integrated circuit, a set of integrated circuits, a microcontroller, a microprocessor 222, a collection of discrete electronic components on a printed circuit board (PCB) 224 or the like. The processor may also stand alone or be part of a computer used for operations involving devices other than the blender. It should be noted that the above description is non-limiting, and the examples are but only a few of many possible processors envisioned.

The input apparatus 216 comprises a plurality of touch sensors 218, for example, capacitive sensors, resistive sensors, infrared proximity sensors, and/or the like. The input apparatus 216 additionally comprises a screen 220 that is integrated or operable with the touch sensors 218. The screen 220 visually indicates the location of buttons, switches, and/or controls and displays information regarding the operation of the blender to the user. Such a screen may be made entirely or in part of or otherwise comprise, a liquid crystal display (LCD), light emitting diodes (LED), or similar display components. The screen may further include a glass or clear plastic coating to further protect the screen from unwanted damage. The sensors 218 are physically arranged to form the various buttons, switches, and controls of the input apparatus 216. For example, a group of sensors 218 may be arranged in a circular pattern to form a button location or a long narrow orientation of sensors may form a “slider” control. Sensors 218 may also be located over the entire area of the input apparatus 216. In such an embodiment, the controller 212 may selectively turn on and off particular groups of sensors 218 to form button and control locations. In this way, the input apparatus 216 can have dynamic controls that may operate the blender in a predetermined manner.

In some embodiments, the sensors 218 may be in fixed locations with images corresponding to the functions associated with buttons formed by the sensors 218 overlaid. In other embodiments, the controller 212 may further serve to control a display on the screen 220 of the input apparatus 216. For example, the controller 212 may operate the LCD, LED, or similar displays to show the location of such dynamic controls. Operation of the displays may also provide feedback associated with the operation of the blender 200. In such embodiments, sensors may be attached to the various components of the functional apparatus 202. For example, a sensor may sense the rotations per minute (RPM) of a motor 210, temperature of a motor 210, presence of a container 204, presence of a lid on a container 204, operational status of the blender 200 and the like. The controller 212 receives the sensor information and controls the screen 220 to display the sensor information in a desired manner or form.

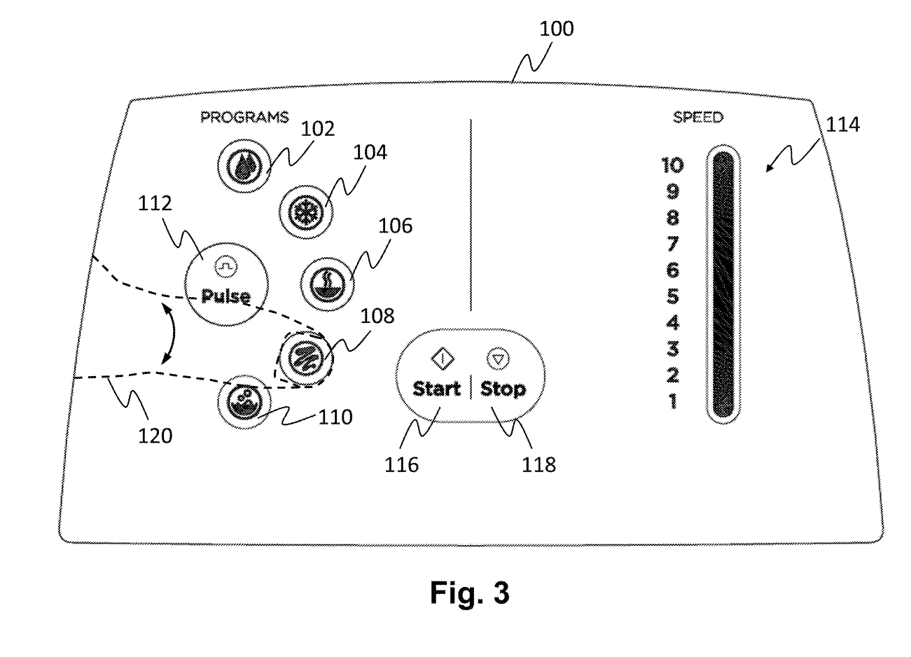

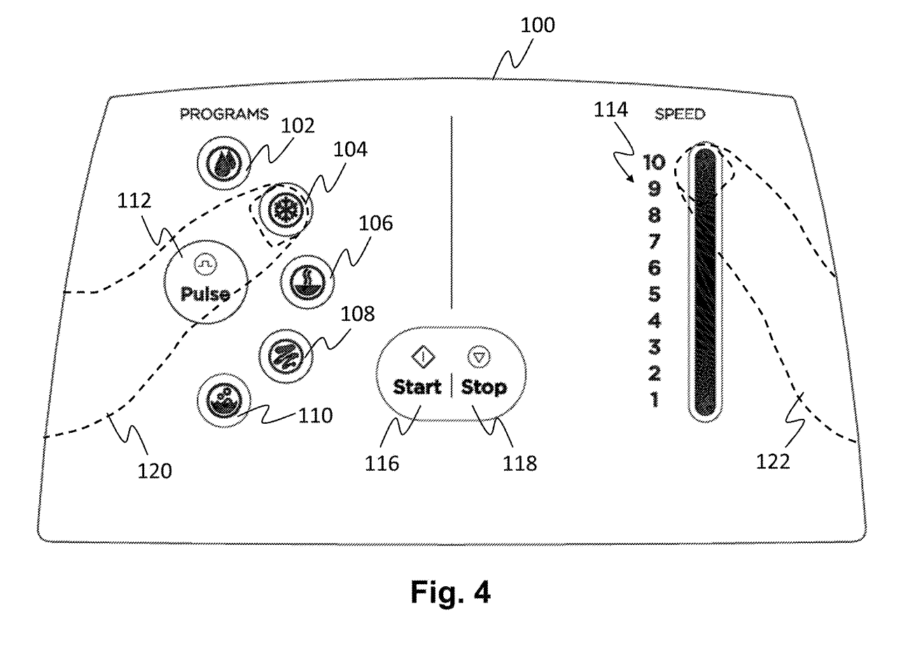

Turning now to an exemplary embodiment, FIGS. 3 and 4 illustrate an input apparatus 216 with touch controls 218 for a blender being operated by a user's thumb. More specifically, FIG. 3 illustrates a screen 100 of an input apparatus in order to show the organization of the touch sensors as capacitive touch controls. The touch sensors 218, however, may be of any appropriate construction, including, without limitation resistive sensors, infrared proximity sensors, and/or the like. The screen 100 can be divided into left, right, and middle portions. The left portion comprises touch buttons for each of a plurality of programs for operating a blender. Such programs represent pre-programmed controls of the functional apparatus 202. By way of a non-limiting example, touch buttons may be included for programs for making smoothies 102, frozen desserts 104, hot soups 106, purees 108, and for washing the blender 110. The present teachings may include additional or alternative program touch buttons. Those shown are merely exemplary. The functional apparatus 202 operates, for example, according to the hardness of the food, desired temperature, and desired consistency.

The buttons for each of the plurality of programs are arranged in an arcuate or semi-circular manner with the curve of the arcuate shape opening toward the side of the blender on which the controls are located (e.g., the left, in FIG. 3). The curvature of the arcuate shape may be of any degree. In one example, the curvature corresponds to the articulation of a thumb 120. That is, the curvature corresponds to a semi-circle with a radius about equal to the average length of a thumb. As described below, such an arrangement places the buttons of the arcuate shape in reach of the thumb during operation.

FIGS. 3 and 4 illustrate the location of a user's left thumb 120 at two locations: over the puree button 108 in FIG. 3 and over the frozen desert button 104 in FIG. 4. As can be seen in these figures, the sliding movement of the thumb 120 corresponds with the curve of the touch buttons 102-110. As a thumb is generally more able to articulate inward or up towards the index finger, the touch buttons arranged in the arcuate shape may angled downward slightly so that a level position of the thumb (perpendicular to the index finger) corresponds with the lower most button (washing 110, in FIG. 3). As the thumb moves upward, it may pass over each of the touch buttons before reaching the top-most touch button (e.g., ‘for smoothies’ 102, in FIG. 3).

For embodiments that utilize a dynamic input apparatus 216, the arrangement of the touch controls may be customized for a particular user, model of blender, intended use of blender, etc. For example, the location and shape of the buttons may be customized for a user's hand size, or controls for the types and number of programs may be selectively active and displayed on the screen 220 based on the model of the blender 200. Further, touch controls may be included in the blender 200 and depending upon the functionality of the blender 200, some of the touch controls may be deactivated from use. For example, the same number and types of touch controls may be used with different models of blenders—so as to achieve a cost saving. In such blenders certain of the touch controls may be activated while the remaining ones deactivated based upon the particular model of blender.

Still referring to FIG. 3, inside of the curvature is a touch button for a pulsating function 112 of the blender which operates the blender for as long as the touch button 112 remains activated (by continuous touch) in conjunction with the selected speed, as discussed below. This touch button may also be operated by the user's thumb given the touch button location relative to the user's hand or thumb. The touch buttons may also be spaced apart by any incremental distance along the arcuate curve. In FIG. 3, the buttons are shown as being generally evenly spaced, but are not limited to such.

The right portion of the screen 100 in FIG. 3 comprises touch sensors arranged to form a vertical sliding speed control 114 that controls the speed of a motor 210 of the blender. As with the touch buttons discussed above, the sliding speed control may also be controlled by articulation of a user's thumb 122, as shown in FIG. 4. As illustrated, the scale of the speed control 114 is from 1-10 (slow to fast), with the slowest speed located nearer to the bottom of the screen, but any scale may be used that indicates to a user various speeds between a minimum and a maximum. Other scales may include fewer variable speeds such as high and low or high, medium, and low. Also, the sliding speed control 114 may be positioned such that the slowest speed is located nearer the top of the screen 100.

It should also be understood that the orientation of the controls may be flipped. That is, the touch buttons for the plurality of programs (102-112) may be located in the right portion and the speed control 114 may be located in the left portion. In other embodiments, the speed control 114 may be horizontal, for example, with the slowest speed nearer to the middle portion of the screen 100—or with the slowest speed nearer the end of the screen 100. Finally, start and start/stop buttons 116, 118 to turn on and off the operation of the blender, in accordance with the selection of the speed 114, are arranged in a lower half of the middle portion. When placed in the lower half of the middle portion, or more generally, nearer to a slower speed control selection, the accidental actuation of the speed control by a user while trying to start or stop the blender can be mitigated.

With the arrangement described above, a user may operate the blender 200 by placing his or her hands on the sides of a base of the blender 200. The thumbs of the hands can be used to control the operation of the blender 200 by operating the touch controls. That is, the left thumb may be used to select a desired program or pulse the contents of the blender 200 (or if positioned opposite of that the right thumb may be used to control such). As discussed above and illustrated in FIGS. 3 and 4, the curvature of the position of the buttons 102-110 for selecting the desired programs corresponds to the articulation or natural extension of a user's thumb 120. Thus, the user may know which program is selected (or will be selected) by knowing at what relative degree to articulate the thumb to reach each button. That is, the user has an awareness of which program is selected by the relative degree of extension of his or her thumb. The other thumb 122 may similarly be used to control the speed slider 114 where full articulation of the thumb 122 corresponds to a maximum or minimum speed depending on the orientation of the speed slider 114. By placing both hands on either side of or on the base of the blender 200 during use, the user has a reference point from which muscle memory can be developed, and at the same time, the user is able to maintain a secure hold of the blender 200. Therefore, the blender 200 may be operated effectively as desired using touch controls without the need to divert one's focus away from the blending operation occurring in the container.

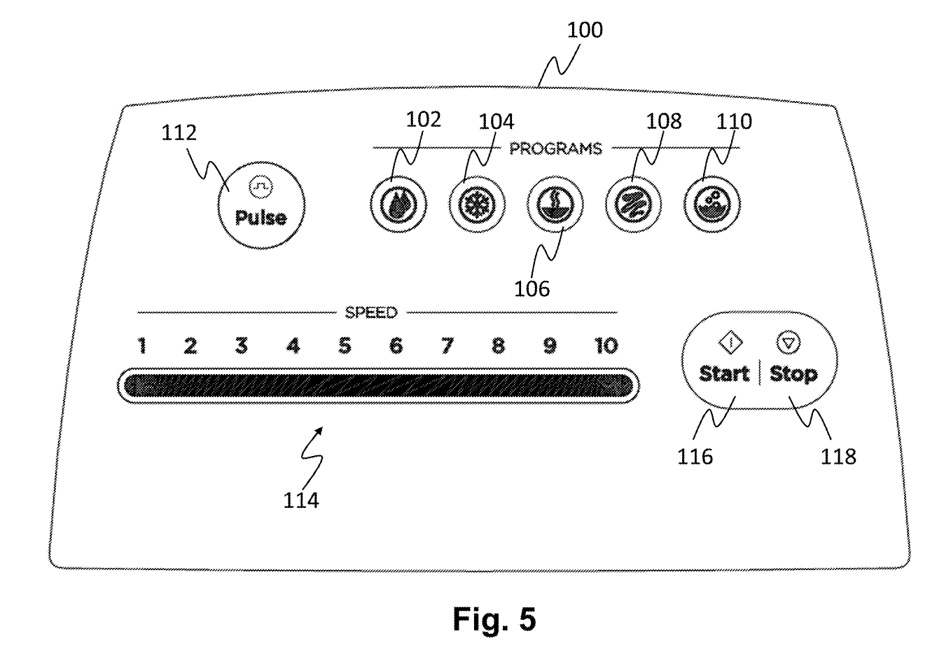

Another exemplary arrangement of touch controls 218 for an input apparatus 216 is illustrated in FIG. 5. The embodiment of FIG. 5 illustrates similar controls as those in FIGS. 3 and 4 as described above. Referring to the arrangement illustrated in FIG. 5, touch buttons for the various programs 102-110 and the sliding speed control 114 are arranged in a horizontal manner in the top right and middle/bottom left corners of the screen 100, respectively. The pulse button 112 and start/stop buttons 116, 118, are positioned apart from the other controls and are located near the top left and middle/bottom right corners of the screen 100, respectively. With this arrangement, an index or other finger of a user may be used to pre-select various settings (e.g., the desired speed and program for operation) and the thumbs may be articulated in the manner previously discussed to control the operative state of the blender 200. However, it remains possible to actuate the remaining buttons and controls by articulating the thumbs as previously discussed. By using geometric patterns such as a horizontal alignment, the arrangement of FIG. 5 also facilitates muscle memory. While not presently illustrated, a similar vertical arrangement of the controls is also envisioned. Further arrangements are envisioned where commonly desired controls are separated (as with the pulse button 112, and start/stop buttons 116, 118 as shown in FIG. 5) for easier control by articulation of the fingers. For example, the slider speed control 114 may have an arcuate shape, rather than be linear as shown, while the pulse button 112 may be arranged closer or adjacent to the program buttons 102-110. In this case, the slider speed control 114 may be more easily operated by articulation of one thumb while the start/stop buttons 116, 118 may be operated by the other thumb.

The various controls described above may also provide visual feedback if a user were to glance at the input apparatus 216. For example, each of the buttons or other controls may be backlit when selected or otherwise being operated. That is, when the controller 212 receives a signal that the touch sensors 218 for a particular button have been activated, the controller may activate a light in the same or nearby physical location to indicate that the button has been activated, for example, by controlling the screen 220 of the input apparatus 216. A similar lighting system may be used to indicate that an error has occurred or that the functionality associated with the button cannot be activated. For a sliding scale, such as the speed, the speed slider 114 may be lit along the scale to indicate the current degree of the selection. For example, FIG. 3 indicates that a speed of “10” has been selected. It should be noted that backlighting is one example of providing visual feedback and that any appropriate visual feedback may be used.

In embodiments where the screen is an LCD or LED display, the display on the screen may be changed to indicate the activation of certain controls. For example, the display of a selected program button may be enlarged or change color when that program has been selected. It may also be desirable to turn off the touch sensors 218 and display for non-selected programs and other unnecessary controls while the blender is being operated. In other words, when a user has selected, e.g., the puree program, the display of the screen 220 may be changed to show or illuminate only the puree button 108 and the stop button 118. Similarly, when pulsing the contents of the blender, only the pulse button 112, speed slider 114, and stop button 118 may remain active and visible on the screen 220. Other non-visual feedback may also be provided in the form of static or varied vibration using motors or piezoelectric devices or sounds such as a series of tones to indicate which particular speed and/or operation has been selected. Any combination of lighting, color, vibrations, and sounds/tones may be employed. Again, the controller 212 would operate such functionalities of the input apparatus 216. While these are just a few examples, they should not be seen as limiting embodiments.

Certain terminology is used herein for convenience only and is not to be taken as a limitation on the present invention. Relative language used herein is best understood with reference to the drawings, in which like numerals are used to identify like or similar items. Further, in the drawings, certain features may be shown in somewhat schematic form.

It is also to be noted that the phrase “at least one of”, if used herein, followed by a plurality of members herein means one of the members, or a combination of more than one of the members. For example, the phrase “at least one of a first widget and a second widget” means in the present application: the first widget, the second widget, or the first widget and the second widget. Likewise, “at least one of a first widget, a second widget and a third widget” means in the present application: the first widget, the second widget, the third widget, the first widget and the second widget, the first widget and the third widget, the second widget and the third widget, or the first widget and the second widget and the third widget. Finally, the term “substantially,” if used herein, is a term of estimation.

While various features are presented above, it should be understood that the features may be used singly or in any combination thereof. Further, it should be understood that variations and modifications may occur to those skilled in the art to which the claimed examples pertain. The examples described herein are exemplary. The disclosure may enable those skilled in the art to make and use alternative designs having alternative elements that likewise correspond to the elements recited in the claims. The intended scope may thus include other examples that do not differ or that insubstantially differ from the literal language of the claims. The scope of the disclosure is accordingly defined as set forth in the appended claims.

What is claimed is:

1. A blending apparatus comprising:
an input apparatus;
a controller;
a motor; and
a container,
wherein the input apparatus comprises a plurality of touch sensors arranged to form a plurality of touch controls, the plurality of touch controls arranged to be operated by articulation of a user's thumb about an axis of rotation while holding the blending apparatus.

2. The blending apparatus according to claim 1, wherein the input apparatus comprises first side, second side, and middle portions,
wherein the plurality of touch controls comprise buttons corresponding to a plurality of blending programs on the first side portion, a speed control on the second side portion, and start and stop buttons in the middle portion, and
wherein, the plurality of blending programs are arranged, in part, in an arcuate manner.

3. The blending apparatus according to claim 2, wherein a touch control for a pulsating function is arranged in the curvature defined by the arcuate arrangement of the buttons corresponding to the plurality of blending programs.

4. The blending apparatus according to claim 3, wherein the curvature defined by the arcuate arrangement opens to the first side of the blending apparatus.

5. The blending apparatus according to claim 2, wherein the speed control is a slider control.

6. The blending apparatus according to claim 2, wherein the plurality of blending programs comprise programs for operating the blending apparatus to create smoothies, frozen desserts, and hot soups.

7. The blending apparatus according to claim 5, further comprising programs for operating the blending apparatus to create purees and to clean the blending apparatus.

8. The blending apparatus according to claim 1, wherein the plurality of touch sensors comprise at least one capacitive touch sensor.

9. The blending apparatus according to claim 1, wherein the input apparatus further comprises a light emitting diode (LED) or liquid crystal display (LCD) screen on which the touch controls are displayed.

10. The blending apparatus according to claim 9, wherein the controller is capable of dynamically altering an arrangement or appearance of the touch controls on the screen.

11. The blending apparatus according to claim 1, wherein the input apparatus further comprises at least one of a series of sounds or vibrations for each of the plurality of touch controls.

12. An input apparatus for a kitchen appliance comprising:
first side, second side, and middle portions; and
a plurality of touch sensors arranged to form a plurality of touch controls,
wherein the plurality of touch controls comprise buttons corresponding to a plurality of programs relating to the operation of the kitchen appliance on a first side portion and start and stop buttons in one of the middle portion and the second side portion,
wherein the plurality of touch controls are arranged to be operated by articulation of a user's thumb about an axis of rotation while holding the kitchen appliance.

13. The input apparatus according to claim 12, wherein the buttons are arranged in an arcuate shape, the curve of the arcuate shape opening toward the first side of the kitchen appliance.

14. The input apparatus according to claim 12, wherein the kitchen appliance is a blender.

15. The input apparatus according to claim 12, wherein the plurality of touch sensors comprise at least one capacitive touch sensor.

16. The input apparatus according to claim 12, further comprising a light emitting diode (LED) or liquid crystal display (LCD) screen.

17. The input apparatus according to claim 16, wherein an arrangement or appearance of the touch controls can be dynamically altered on the screen.

18. The input apparatus according to claim 16, wherein the screen is divided into multiple sections corresponding to the plurality of touch controls and illuminates in one or more different colors according to an activated touch control and relative speed.

19. The input apparatus according to claim 12 further comprising at least one of a series of sounds or vibrations for each of the plurality of touch controls.

20. The input apparatus according to claim 12, wherein the plurality of touch controls are arranged to be operated by articulation of the user's thumb on one hand while activating a speed control with the user's thumb on the other hand.
